(19) United States
(12) Patent Application Publication
(10) Pub. No.: US 2009/0166687 A1
(43) Pub. Date: Jul. 2, 2009

(54) Image Sensor and Method for Manufacturing the Same

(76) Inventor: Jong Man KIM, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/265,669

(22) Filed: Nov. 5, 2008

(30) Foreign Application Priority Data
Dec. 27, 2007 (KR) 10-2007-0139266

(51) Int. Cl. H01L 31/112; H01L 31/18

(52) U.S. Cl. 257/290; 438/57; 257/E31.079

(57) ABSTRACT

An image sensor and a method for manufacturing the same may include a gate on a semiconductor substrate, a photodiode on the semiconductor substrate at a first side of the gate, a floating diffusion region on the semiconductor substrate at a second side of the gate, in which the second side is opposite to the first side, a channel under the gate, the channel connecting the photodiode with the floating diffusion region, and a barrier region under the photodiode.

The present application claims priority under 35 U.S.C. 119 to Korean Patent Application No. 10-2007-0139266 (filed on Dec. 27, 2007), which is hereby incorporated by reference in its entirety.

### BACKGROUND

Embodiments of the present invention relate to an image sensor and a method for manufacturing the same.

An image sensor is a semiconductor device for converting an optical image into an electric signal. Image sensors may be classified into charge coupled device (CCD) image sensors and complementary metal oxide silicon (CMOS) image sensors (CIS).

A CIS includes a photodetecting part that detects light and a logic circuit part that processes detected light into an electrical signal to generate data. A CIS employs a switching scheme to sequentially detect outputs of pixels through MOS transistors provided corresponding to the number of the pixels.

As the CIS is highly integrated, the size of a unit pixel is proportionally reduced, so that a photodiode, which is a photo response region, is relatively reduced. In particular, a visible ray incident upon the photodiode creates electron-hole pairs at various depths of the photodiode according to the intensities of red, green, and blue wavelengths. The depths are determined according to the skin depth of each wavelength. The depth is the shallowest in the blue wavelength, and the deepest in the red wavelength.

Accordingly, if the depth of a photodiode region is not reduced, variations may occur in short and long wavelengths, so that the quality of an image sensor may be degraded.

### SUMMARY

Embodiments of the present invention relate to an image sensor and a method for manufacturing the same, capable of improving photosensitivity of a photodiode.

According to embodiments of the present invention, an image sensor may include a gate on a semiconductor substrate, a photodiode on the semiconductor substrate at a first side of the gate, a floating diffusion region on the semiconductor substrate at a second side of the gate, in which the second side is opposite to the first side, a channel under the gate, the channel connecting the photodiode with the floating diffusion region, and a barrier region under the photodiode.

According to other embodiments of the present invention, a method for manufacturing an image sensor may include the steps of forming a channel on a semiconductor substrate, forming a gate on the semiconductor substrate, forming a barrier region in the semiconductor substrate at a first side of the gate, forming a photodiode above the barrier region, and forming a floating diffusion region at a second side of the gate on the semiconductor substrate, the second side of the gate being opposite to the first side of the gate.

### BRIEF DESCRIPTION OF THE DRAWINGS

FIGS. 1 to 6 are sectional views showing an exemplary manufacturing process of an image sensor according to embodiments of the present invention.

### DETAILED DESCRIPTION OF THE EMBODIMENTS

Hereinafter, an image sensor and a method for manufacturing the same according to embodiments of the present invention will be described with reference to accompanying drawings.

FIG. 6 is a sectional view showing an exemplary image sensor according to an embodiment of the present invention.

Referring to FIG. 6, an image sensor according to the embodiment may include a gate 50 that is formed on a semiconductor substrate 10, a photodiode 70 formed on the semiconductor substrate 10 at one side of the gate 50, a floating diffusion region 90 formed at the other side of the gate 50 on the semiconductor substrate 10, a channel 40 that is formed under the gate 50 and connects the photodiode 70 with the floating diffusion region 90, and a barrier region 60 formed under the photodiode 70.

The semiconductor substrate 10 may comprise single-crystalline silicon. The semiconductor substrate 10 may be doped with p type dopants or n type dopants. According to one embodiment, the semiconductor substrate 10 is a heavily-doped p type semiconductor substrate, and includes a lightly-doped p type epitaxial layer (p-epi).

The barrier region 60 formed at one side of the gate 50 may be spaced apart from the surface of the semiconductor substrate 10 by a first depth D. For example, the first depth D may be in the range of about 1000 Å to 1500 Å. In other words, the barrier region 60 may be spaced apart from the surface of the semiconductor substrate 10 and formed at a depth of about 1000 Å to 1500 Å. The barrier region 60 may be heavily doped with p type dopants.

The photodiode 70 may be formed above the barrier region 60. The photodiode 70 may include a first conductive region 71 formed above the barrier region 60 and a second conductive region 72 formed above the first conductive region 71. The first conductive region 71 may be doped with n-type dopants, and the second conductive region 72 may be doped with p type dopants. Accordingly, the photodiode 70 may have a p/n/p structure and may be formed in the semiconductor substrate 10 at one side of the gate 50 to generate photoelectrons.

The photodiode 70 may be formed with a lower depth of approximately 1000 Å from the surface of the semiconductor substrate 10 (but above the barrier region 60) to more uniformly maintain photosensitivity. In other words, since the photodiode 70 may be restricted in depth from the surface of the semiconductor substrate 10 to the barrier region 60, the photodiode 70 can maintain uniform and/or balanced photosensitivity for blue, green, and red wavelengths. Accordingly, the photosensitivity of the photodiode can be improved. In particular, if the depth of the photodiode 70 is restricted, the photodiode may have a light absorption coefficient for red wavelengths (generally, a long wavelength at low luminance) that can be maintained consistent with coefficients for other colors, thereby providing uniform and/or balanced photosensitivity similar to that of the blue and green colors.

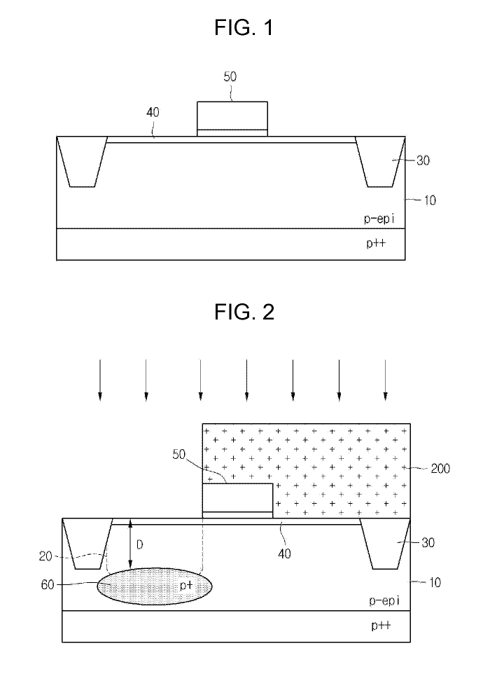

Hereinafter, an exemplary method for manufacturing an image sensor will be described with reference to FIGS. 1 to 6.

Referring to FIG. 1, the gate 50 may be formed on the semiconductor substrate 10 including the p-epi layer. The semiconductor substrate 10 may include single-crystalline silicon, and may be doped with p type dopants or n-type dopants. According to one embodiment, the semiconductor substrate 10 is a heavily-doped p type semiconductor substrate 10. In addition, the semiconductor substrate 10 may include a lightly-doped p type epitaxial (p-Epi) layer formed through an epitaxial process.

The reasons for forming the lightly-doped p type epitaxial layer (p-epi) on the heavily-doped p type semiconductor substrate 10 are as follows. First, a depletion region of the photodiode 70 can be enlarged and/or deepened due to the lightly-doped p type epitaxial layer, so that the capability of the photodiode 70 to collect optical charges can be increased. Second, when the heavily-doped p+substrate is formed under the p type epitaxial layer, optical charges are quickly recombined before the optical charges are diffused into an adjacent unit pixel, so that the random diffusion of optical charges is reduced. Accordingly, variation in the delivery of the optical charges can be reduced. Although the semiconductor substrate 10 and the epitaxial layer may be doped with p type dopants, embodiments of the present invention are not limited thereto.

A plurality of isolation layers 30 may be formed on the semiconductor substrate 10 to define an active region and a field region. The surface of the semiconductor substrate 10 may be implanted with p0 ions, thereby forming the channel 40 to adjust a threshold voltage and carry charges.

The gate 50 may be formed on the channel 40. The gate 50 may be a gate of a transfer transistor. The gate 50 may be formed by depositing a gate insulating layer and a gate conductive layer and then patterning the resultant structure. For example, the gate insulating layer may be an oxide layer, and the gate conductive layer may have a single layer structure or a multi-layer structure comprising polysilicon, a metal such as tungsten, and/or a metal silicide.

Referring to FIG. 2, the barrier region 60 may be formed at one side of the gate 50 and at a deep region of the semiconductor substrate 10. The barrier region 60 may define a photodiode region 20. The barrier region 60 may be spaced apart from the surface of the semiconductor substrate 10 by a first depth D. When the barrier region 60 is formed inside the semiconductor substrate 10, an upper portion of the barrier region 60 may overlap with the photodiode region 20. The barrier region 60 may be heavily doped with p type dopants.

In order to form the barrier region 60, a photoresist pattern 200 may be formed to expose the substrate active area on one side of the gate 50. Then, a heavy dose of a p type dopant may be implanted into the inside of the semiconductor substrate 10 by an ion implantation process. For example, the barrier region 60 may be formed by implanting boron (B) ions into the semiconductor substrate 10 in a projection range of about 0.1 μm to 1.5 μM at an energy of about 700 KeV to 1000 KeV. Barrier region 60 may be formed in the epitaxial layer of the semiconductor substrate 10. In other words, the barrier region 60 may be formed at a region spaced apart from the surface of the semiconductor substrate by a distance of about 1000 Å to 1500Å. When the barrier region 60 is formed inside the epitaxial layer, the size of the photodiode 70, which is formed in a subsequent process, can be restricted. That is, when the barrier region 60 is formed in a deep region of the semiconductor substrate 10, the photodiode 70, which is formed in a subsequent process, may be formed above barrier region 60, so that the depletion region of the photodiode 70 can be defined.

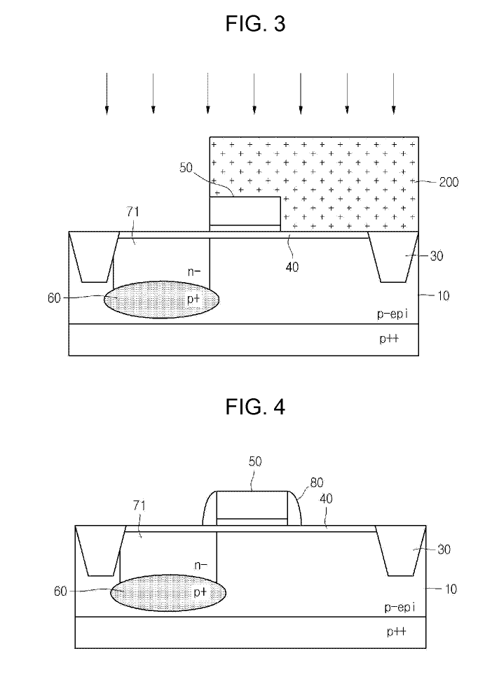

Referring to FIG. 3, a first conductive region 71 of the photodiode 70 may be formed in the photodiode region 20. The first conductive region 71 may be formed in the photodiode region 20 adjacent to or overlapping an upper portion of the barrier region 60. For example, the first conductive region 71 may be formed by implanting an n-type dopant. In particular, the first conductive region 71 may be formed by implanting an n-type dopant into the semiconductor substrate 10 exposed by the photoresist pattern 200, which has been used in the formation of the barrier region 60, as an ion implantation mask. The first conductive region 71 may be formed only in the photodiode region 20, on the barrier region 60. Photoresist pattern 200 may then be removed by ashing (e.g., plasma treatment with oxygen), followed by wet cleaning.

Referring to FIG. 4, a spacer 80 may be formed at sidewalls of the gate 50. The Spacer 80 may be formed by depositing an insulating layer on the semiconductor substrate 10, including on the gate 50, and then anisotropically etching the entire surface of the resultant structure. For example, the spacer 80 may comprise an oxide layer, a nitride-on-oxide bilayer, or an oxide-nitride-oxide structure.

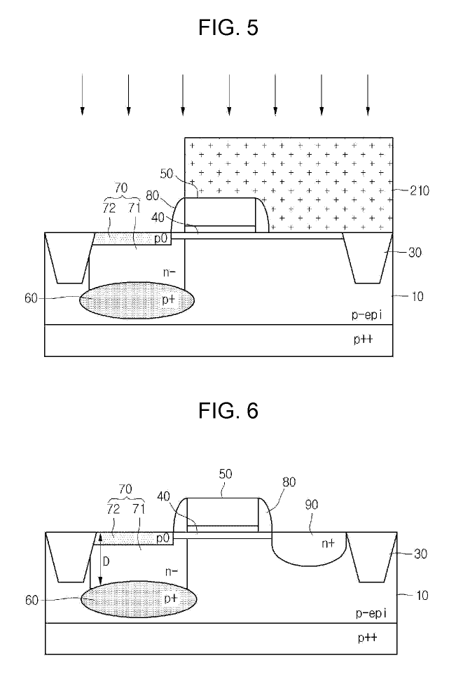

Referring to FIG. 5, a second conductive region 72 may be formed on the first conductive region 71. The second conductive region 72 may be formed on, at or near the surface of the semiconductor substrate 10 at one side of the gate 50.

The second conductive region 72 may be formed by forming a photoresist pattern 210 such that the surface of the semiconductor substrate 10 at one side of the gate 50 is exposed. The photoresist pattern 210 may be formed by using the same mask used to form the photoresist pattern 200 shown in FIG. 2. A P type dopant may be implanted into the surface of the semiconductor substrate 10 by using the photoresist pattern 210 as an ion implantation mask. Accordingly, the second conductive region 72 may be formed at an upper portion of the first conductive region 71 of the semiconductor substrate 10.

Accordingly, the photodiode 70, which may comprise first and second conductive regions 71 and 72, may be formed in the photodiode region 20 defined by the barrier region 60. The photodiode 70 may be formed on the barrier region 60 to have the first depth D. The photodiode 70 may have a depth of about 10 Å to 1000 Å from the surface of the semiconductor substrate 10.

The photodiode 70 may be formed in an area restricted by the barrier region 60, so that the photosensitivity of the photodiode 70 can be improved. In detail, a visible ray incident upon the photodiode 70 creates electron-hole pairs at depths according to intensities of red, green, and blue wavelengths. The depth is determined according to the skin depth of each wavelength. The skin depth is the shallowest in the blue wavelength, and the deepest in the red wavelength. For example, the blue wavelength is detected in a region of approximately 400 Å distanced from the surface of the photodiode 70. The green wavelength is detected in a region of approximately 400 Å to 700 Å from the surface of the photodiode 70, and the red wavelength is detected in a region of approximately 700 Å or less from the surface of the photodiode 70. Accordingly, if the photodiode 70 is enlarged in depth, the sensitivity for the red wavelength representing a long wavelength is increased as compared with those of the blue or green wavelength, so that the photosensitivity of the photodiode 70 may be degraded.

According to embodiments of the present invention, the depletion region of the photodiode 70 may be restricted by the barrier region 60. In other words, since the barrier region 60 is formed at a depth of about 1000 Å to 1500 Å from the surface of the semiconductor substrate 10, the photodiode 70 may be formed within a restricted region of a maximum depth of approximately 1000 Å from the surface of the semiconductor substrate 10. Accordingly, if light is incident upon the photodiode 70 formed above barrier region 60, a region in which the red wavelength representing a long wavelength is detected is reduced. In other words, the regions of the photodiode 70, in which the blue, green, and red signals are detected, can be made more uniform and/or balanced. Accordingly, the photodiode 70 may more uniformly create photoelectrons with respect to the blue, green, and red wavelengths, so that the photosensitivity of the photodiode can be improved.

Referring to FIG. 6, the floating diffusion region 90 may be formed at an opposite side of the gate 50. The floating diffusion region 90 may be formed by heavily doping n+ dopants into the opposite side of the gate 50.

In an exemplary method for manufacturing an image sensor according to an embodiment of the present invention, the photodiode is formed in a restricted region, so that the photosensitivity of the photodiode can be improved. In particular, since photoelectrons are more uniformly created and/or balanced with respect to green, blue, and red wavelengths under low luminance, the photosensitivity of the photodiode can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a gate on a semiconductor substrate;
a photodiode in the semiconductor substrate at a first side of the gate;
a floating diffusion region in the semiconductor substrate at a second side of the gate, in which the second side is opposite to the first side;
a channel under the gate, the channel connecting the photodiode with the floating diffusion region; and
a barrier region under the photodiode.

2. The image sensor of claim 1, wherein the barrier region is formed at a depth of about 1000 Å to 1500 Å from a surface of the semiconductor substrate.

3. The image sensor of claim 1, wherein the barrier region comprises a heavy dose of a p type dopant.

4. The image sensor of claim 1, wherein the photodiode comprises a first conductive region doped with an n-type dopant and a second conductive region doped with a p type dopant.

5. The image sensor of claim 4, wherein the second conductive region is above the first conductive region.

6. The photodiode of claim 4, wherein the second conductive region has a depth of about 10 Å to 1000 Å from a surface of the semiconductor substrate.

7. A method for manufacturing an image sensor, the image sensor comprising the steps of:
forming a channel on a semiconductor substrate;
forming a gate on the semiconductor substrate;
forming a barrier region in the semiconductor substrate at a first side of the gate;
forming a photodiode above the barrier region; and
forming a floating diffusion region at a second side of the gate on the semiconductor substrate, the second side of the gate being opposite to the first side of the gate.

8. The method of claim 7, wherein the step of forming the barrier region comprises the steps of:
forming a first photoresist pattern exposing a portion of the semiconductor substrate; and
performing an ion implantation process on or in the exposed portion of the semiconductor substrate.

9. The method of claim 8, wherein the step of forming the photodiode comprises the steps of:
forming a second photoresist pattern exposing a portion of the semiconductor substrate containing the barrier region;
forming a first conductive region by implanting an n-type dopant into the portion of the semiconductor substrate containing the barrier region; and
forming a second conductive region by implanting a p type dopant into the first conductive region.

10. The method of claim 7, wherein the step of forming the photodiode comprises the steps of:
forming a photoresist pattern exposing a portion of the semiconductor substrate containing the barrier region;
forming a first conductive region by implanting n-type dopants into the portion of the semiconductor substrate containing the barrier region; and
forming a second conductive region by implanting p type dopants into the first conductive region.

11. The method of claim 7, wherein the barrier region comprises a heavy dose of a p type dopant.

12. The method of claim 9, wherein the first and second photoresist patterns are formed using a single mask.

13. The method of claim 7, wherein the barrier region is formed at a depth of about 1000 Å to 1500 Å from a surface of the semiconductor substrate.
